(19) United States
(12) Patent Application Publication
(10) Pub. No.: US 2012/0088081 A1
(43) Pub. Date: Apr. 12, 2012

(54) COATED ARTICLE AND METHOD OF MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); SHUN-MAO LIN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/172,209

(22) Filed: Jun. 29, 2011

(30) Foreign Application Priority Data
Oct. 6, 2010 (CN) 201010299020.5

(51) Int. Cl. B32B 3/10; C23C 14/04; C23C 14/35; C23C 14/02

(52) U.S. Cl. 428/209; 428/195.1; 428/210; 427/571

(57) ABSTRACT

A coated article includes a substrate and a pattern layer formed on the substrate. The pattern layer includes a plurality of strips. Each area of these strips is in a range of about 0.001 mm² to about 0.025 mm² A distance between two adjacent strips is in a range of about 0.02 mm to about 0.04 mm.

### BACKGROUND

1. Technical Field

This disclosure relates to coated articles, particularly, to a coated article with a pattern and a method of making the same.

Laser engraving and chemical etching are two typical methods for forming an engraved pattern on a surface of a substrate. However, it is hard to form a uniform matt surface on the substrate applying these methods.

Therefore, there is room for improvement within the art.

### BRIEF DESCRIPTION OF THE DRAWING

Many aspects of the coated article and method of making the same can be better understood with reference to the following drawing. The components in the drawing are not necessarily drawn to scale, the emphasis instead being placed upon clearly illustrating the principles of the coated article and method of making the same.

FIG. 1 is a schematic view of a coated article, in accordance with an exemplary embodiment.

FIG. 2 is a flow schematic view of making the coated article shown in FIG. 1.

FIG. 3 is a partially microscopically magnified view of a substrate coated with a photoresist layer after a heat treatment and a cold treatment, in accordance with an exemplary embodiment.

### DETAILED DESCRIPTION

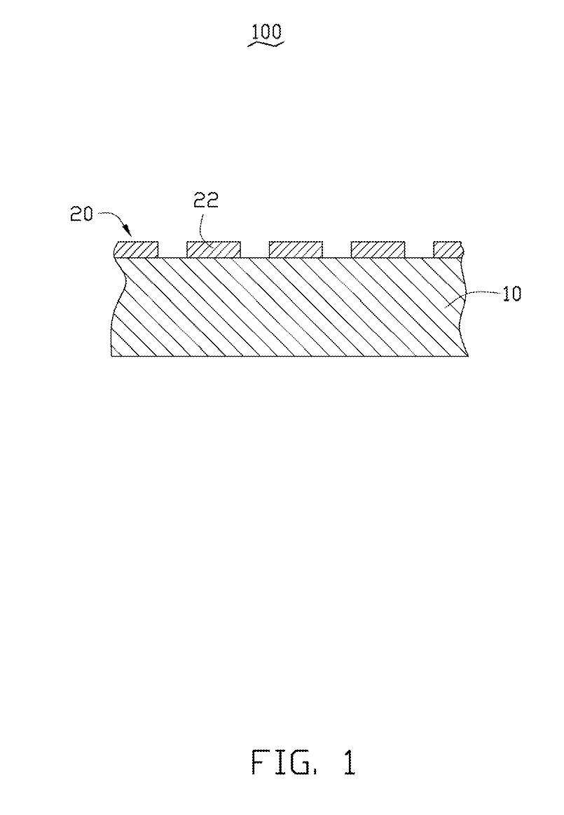

FIG. 1 shows an exemplary embodiment of a coated article 100. The coated article 100 includes a substrate 10 coated with a pattern layer 20. The pattern layer 20 includes a plurality of strips 22 which do not contact each other. An area (total surface) of each strip 22 is in a range of about 0.001 mm² to about 0.025 mm². A distance between two adjacent strips 22 is in a range of about 0.02 mm to about 0.04 mm. The shapes of the strip 22 may be varied, e.g., dots or squares in different sizes. These strips 22 give the article a matt surface, which can be aesthetically pleasing.

The substrate 10 may be made of metal, e.g., stainless steel, aluminum alloy, magnesium alloy, or non-metal, e.g., glass.

The pattern layer 20 may be formed by magnetron sputtering, and is made of one or one more of metal, metal oxide, metal carbide, metal nitride, metal oxycarbide, and metal oxynitride.

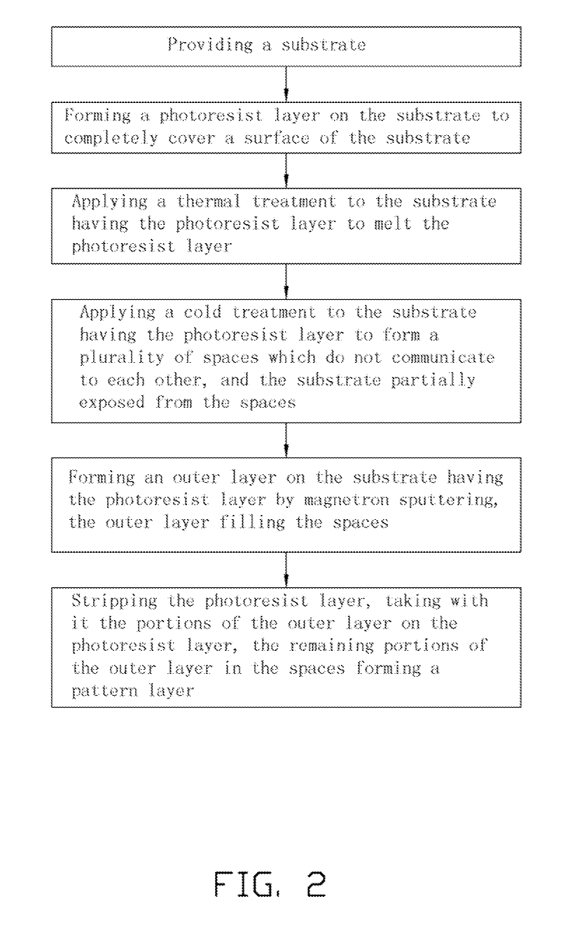

Referring to FIG. 2, a method of making the coated article 100 includes the following steps:

A substrate 10 is provided. The substrate 10 may be a metal, e.g., stainless steel, aluminum alloy, magnesium alloy, or non-metal, e.g., glass.

A photoresist layer 11 is formed on the substrate 10 to completely cover a surface of the substrate 10. In this exemplary embodiment, the photoresist layer 11 is sprayed on. The photoresist layer 11 is made of positive photoresist, which can be bought from CHI MEI COMMUNICATION SYSTEMS, INC. A thickness of the photoresist layer 11 is in a range of 10 μm to 40 μm.

A heat treatment is applied to the substrate 10 having the photoresist layer 11. In the heat treatment, the photoresist layer 11 is heated to a temperature in a range of about 150° C. to about 260° C., and this temperature is maintained for about 15 minutes (min) to about 60 min. In this exemplary embodiment, the temperature of the photoresist layer 11 is kept at about 250° C. and is maintained for about 40 min. During the heat treatment, the photoresist layer 11 becomes hardened to form a film state at first and then gradually melts. When the photoresist layer 11 melts, a portion of the photoresist evaporates. At the same time, the substrate 10 and the photoresist layer 11 expand.

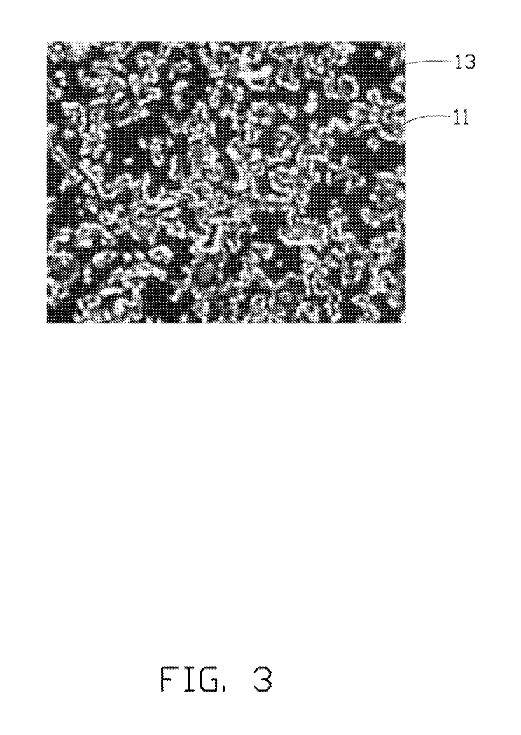

After the heat treatment for the photoresist layer 11, a cold treatment is applied to the substrate 10 having the photoresist layer 11. In this exemplary embodiment, the substrate 10 having the photoresist layer 11 is cooled at a normal atmospheric temperature and a normal atmospheric pressure. Referring to FIG. 3, the photoresist layer 11 shrinks when cooled and randomly to form a plurality of spaces 13 which do not communicate to each other. The substrate 10 is partially exposed through the spaces 13.

The substrate 10 having the photoresist layer 11 is cleaned using deionized water. The substrate 10 having the photoresist layer 11 is sprayed with the deionized water and then is dried at an atmospheric temperature in a range of about 110° C. to about 130° C.

An outer layer is formed on the substrate 10 having the photoresist layer 11 by magnetron sputtering. The outer layer is positioned on the photoresist layer 11 and fills the spaces 13 of the photoresist layer 11. The portions of the outer layer in the spaces 13 are attached to the surface of the substrate 10. The composite used to form the outer layer can be a selected one or more of metal, metal oxide, metal carbide, metal nitride, metal oxycarbide, and metal oxynitride, according to a desired color of the article. In the process of magnetron sputtering, a metal is applied as a target, and one or one more of oxygen, nitrogen and ethyne is/are applied as reactive gas. A thickness of the outer layer is in a range of about 0.5 μm to about 1.5 μm.

The photoresist layer 11 is stripped, taking with it portions of the outer layer on the photoresist layer 11. The remaining portions of the outer layer in the spaces 13 form the pattern layer 20. In this process, the substrate 10 having the photoresist layer 11 and the outer layer is immersed into a sodium hydroxide solution containing about 8% to about 10% sodium hydroxide by weight or a potassium hydroxide solution containing about 8% to about 10% potassium hydroxide by weight for about 2 min to about 10 min. A temperature of the solution is maintained in a range of about 60° C. to about 90° C. The remaining portions of the outer layer in the spaces 13 form a plurality of discontinuously distributed portions. These portions form the pattern layer 20. Each area of these portions is in a range of about 0.001 mm² to about 0.025 mm². A distance between two adjacent portions is in a range of about 0.02 mm to about 0.04 mm. The portions may be unequal dots or unequal squares. These discontinuously distributed portions give the article the cloudy appearance.

It is to be understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate; and
a pattern layer formed on the substrate, the pattern layer including a plurality of strips which do not connect to each other, an area of each strip being in a range of about 0.001 mm² to about 0.025 mm², a distance between two adjacent strips being in a range of about 0.02 mm to about 0.04 mm.

2. The coated article as claimed in claim 1, wherein the substrate is made of stainless steel, aluminum alloy, magnesium alloy, or glass.

3. The coated article as claimed in claim 1, wherein the pattern layer is made of one or one more of metal, metal oxide, metal carbide, metal nitride, metal oxycarbide and metal oxynitride.

4. A method of making a coated article, comprising steps of:
providing a substrate;
forming a photoresist layer on the substrate to completely cover a surface of the substrate;
applying a heat treatment to the substrate having the photoresist layer to melt the photoresist layer;
applying a cold treatment to the substrate having the photoresist layer to form a plurality of spaces which do not communicate to each other, and the substrate partially exposed from the spaces;
forming an outer layer on the substrate having the photoresist layer by magnetron sputtering, the outer layer filling the spaces; and
stripping the photoresist layer, taking with it the portions of the outer layer on the photoresist layer, the remaining portions of the outer layer in the spaces forming a pattern layer.

5. The method as claimed in claim 4, wherein a thickness of the photoresist layer is in a range of about 10 μm to about 40 μm.

6. The method as claimed in claim 4, wherein the outer layer is made of one or one more of metal, metal oxide, metal carbide, metal nitride, metal oxycarbide and metal oxynitride.

7. The method as claimed in claim 6, wherein the outer layer is formed by magnetron sputtering, in the process of magnetron sputtering, a metal is applied as a target, and one or one more of oxygen, nitrogen and ethyne is/are applied as reactive gas.

8. The method as claimed in claim 4, wherein during the heat treatment, a temperature of the photoresist layer is in a range of about 150° C. to about 260° C., and this temperature is maintained for about 15 minutes (min) to about 60 min.

9. The method as claimed in claim 4, wherein during the step of stripping the photoresist layer, the substrate having the photoresist layer is immersed into a sodium hydroxide solution containing about 8% to about 10% sodium hydroxide by weight or a potassium hydroxide solution containing about 8% to about 10% potassium hydroxide by weight for 2 min to 10 min, and the temperature of the solution is maintained in a range of about 60° C. to about 90° C.

10. The method as claimed in claim 4, wherein a thickness of the outer layer is in a range of about 0.5 μm to about 1.5 μm.
